(19) United States
(12) Patent Application Publication
(10) Pub. No.: US 2026/0264817 A1
(43) Pub. Date: Sep. 10, 2026

(54) Acoustic Metamaterial for Aqueous Environments

(71) Applicant: WISCONSIN ALUMNI RESEARCH FOUNDATION, Madison, WI (US)

(72) Inventors: Chu Ma, Madison, WI (US); Dajun Zhang, Madison, WI (US)

(21) Appl. No.: 19/073,391

(22) Filed: Mar. 7, 2025

(51) Int. Cl. B63B 39/00; H03H 9/24

(52) U.S. Cl. CPC B63B 39/00; H03H 9/24

(57) ABSTRACT

A metamaterial reflector for aqueous use promotes a reflection with a composite of matrix and high-density particles. Raised patterns on the reflecting surface of the reflector provide an acoustic reflection tailored to desired motion including translation, centering, and rotation. Available buoyancy allows acoustic energy to be channeled to non-levitating purposes.

### STATEMENT REGARDING FEDERALLY SPONSORED RESEARCH OR DEVELOPMENT

This invention was made with government support under 2328096 awarded by the National Science Foundation. The government has certain rights in the invention.

### BACKGROUND OF THE INVENTION

The present invention relates generally to acoustic metamaterials and, in particular, to an acoustic metamaterial adapted for aqueous environments.

Acoustic metamaterials are structures having unit cells with subwavelength sizes producing exotic properties that do not exist in natural forms, e.g., negative mass, density and/or bulk modulus, negative refractive index, and negative Poisson's ratio.

Recently, acoustic metamaterials have been used to assist in remote manipulation of large objects (i.e., objects greater than at least twice the wavelength) using acoustic waves transmitted through the air. Without the assistance of metamaterials, acoustic wave can only manipulate objects smaller or comparable to the wavelength, for example, as can be trapped by acoustic standing waves or at the potential wells generated by either a transducer array or a hologram. By using an acoustic metamaterial, however, acoustic waves reflected by the object's surface produce an exchange of momentum between the waves and the object, resulting in an acoustic radiation force on the object allowing larger objects to be both suspended and manipulated.

### SUMMARY OF THE INVENTION

The present inventors have recognized that important applications exist for acoustic manipulation in an aqueous environment. The above metamaterials developed for in-air levitation and manipulation cannot be applied in an aqueous environment. They cannot generate strong enough radiation forces in water because of the small acoustic property mismatch with water. Such an environment not only provides improved sound conduction but also the ability to use buoyancy to aid in levitation freeing acoustic power for manipulation. Such applications are enabled by a material combining a matrix material having desirable mechanical and chemical properties with fine inclusions of a high density material that provokes a necessary acoustic mismatch between the aqueous environment and the material necessary for strong reflection and acoustic force generation. A variety of novel metamaterial surfaces can be readily formed in this material including novel surfaces that promote multiple different types of motion.

More specifically, in one embodiment, the invention provides an acoustic reflector comprised of matrix material having impedance boosting inclusions with a higher density than the matrix material, the acoustic reflector providing a reflection surface exposing a raised surface pattern adapted to preferentially reflect an aqueously transmitted acoustic signal in least one predetermined direction at a nonzero angle with respect to the reflection surface. The impedance boosting inclusions may have an acoustic impedance (Z=ρc) greater than 4.5 MPa·S/m³ and the matrix material has an acoustic impedance less than 3 MPa·S/m³.

It is thus a feature of at least one embodiment of the invention to provide a metamaterials for aqueous environments. The combination of a matrix material and higher density inclusions allows improved mechanical properties, for example, for fabrication, and chemical properties, for environmental resistance, while simplifying the manufacture of the necessary surface patterns.

The inclusions may have a greatest dimension less than 1500 μm.

It is thus a feature of at least one embodiment of the invention to provide an inclusion size that may be readily dispersed in the matrix material and that is small in relationship to an expected wavelength of the received acoustic signal to change the apparent bulk properties of the composite material.

In some embodiments, the inclusions may be a metal or metal compound.

It is thus a feature of at least one embodiment of the invention to provide highly dense materials that maximize impedance mismatch of the metamaterial with water.

The inclusions may have a concentration in a region of the matrix material, within 1500 micrometers of a surface of the acoustic reflector receiving the transmitted acoustic signal, and at least five times an average concentration outside of that region within the matrix material.

It is thus a feature of at least one embodiment of the invention to provide a strong and tractable yet lightweight material by concentrating the inclusions at the surface of the metamaterial in a region having significant interaction with acoustic waves.

The inclusions may have a mass ratio to the matrix, within 1500 micrometers of a surface of the acoustic reflector receiving the transmitted acoustic signal, of less than 85%.

It is thus a feature of at least one embodiment of the invention to provide a material that provides a good trade-off between weight and acoustic reflection in an aqueous environment. The matrix may be a polymer.

It is thus a feature of at least one embodiment of the invention to select a matrix material that can be readily molded, machined, printed, or stamped and that is resistant to many environmental conditions such as those that might cause corrosion of metal.

In some embodiments, the matrix material may be an elastomer.

It is thus a feature of at least one embodiment of the invention to provide a metamaterial that can be wrapped or formed around another object after manufacture.

The predetermined direction of reflection may be selected from a direction angled from a perpendicular to a broadest extent of the reflection surface and a direction having a tangential component around perpendicular to the broadest extent of the reflection surface. In the case of a direction angled from the perpendicular to the broadest extent of the reflection surface, the direction may be such as to center the acoustic reflector about a local maximum of the acoustic signal strength impinging on the reflection surface.

It is thus a feature of at least one embodiment of the invention to provide a variety of different patterns for promoting a set of different reflection types.

In some cases, the predetermined direction may be such as to provide a force promoting a combination of rotation and translation of the acoustic reflector.

Thus it is a feature of at least one embodiment of the invention to provide surfaces that can produce forces that are combinations of pure translation, centering, and rotation.

In some embodiments the surface pattern may include a first sub-pattern adapted to reflect an aqueously transmitted acoustic signal at a first frequency to impose a force along at least one predetermined direction sufficient to move the matrix material in response to that force, and a second sub pattern adapted to reflect an aqueously transmitted acoustic signal at a second frequency different from the first frequency to impose a different force along at least one second different predetermined direction different from the at least one predetermined direction.

It is thus a feature of at least one embodiment of the invention to allow control of an imparted motion through frequency shifting (multiplexing) of the driving ultrasonic signal.

These particular objects and advantages may apply to only some embodiments falling within the claims and thus do not define the scope of the invention.

### BRIEF DESCRIPTION OF THE DRAWINGS

FIG. 1 is a simplified diagram of a manipulated object suspended over an acoustic transmitter in an aqueous environment and showing, in separate detail, features of the manipulated object;

FIG. 2 is a bottom plan and side view of one embodiment of a object of FIG. 1 providing a surface configured for lateral translation of the object under the influence of an acoustic beam of the acoustic transmitter;

FIG. 3 is a figure similar to that of FIG. 2 providing a surface configured to follow the acoustic beam of the acoustic transmitter;

FIG. 4 is a figure similar to that of FIGS. 2 and 3 providing a surface promoting a rotation of the object;

FIG. 5 is a schematic representation of a combination of surfaces, depicted in bottom plan view, to produce a composite surface for simultaneous rotation and translation;

FIG. 6 is a schematic representation of a combination of surfaces depicted in cross-section for providing frequency-selective left and right translation;

FIGS. 7a and 7b are bottom plan views and side views of an object having multiple spatially separated patterns for selective activation by a steerable or modulated acoustic transmitter; and

FIGS. 8a and 8b are representations of a construction of a metamaterial surface that may conform to a curved object to provide the benefits of the present invention.

### DETAILED DESCRIPTION OF THE PREFERRED EMBODIMENT

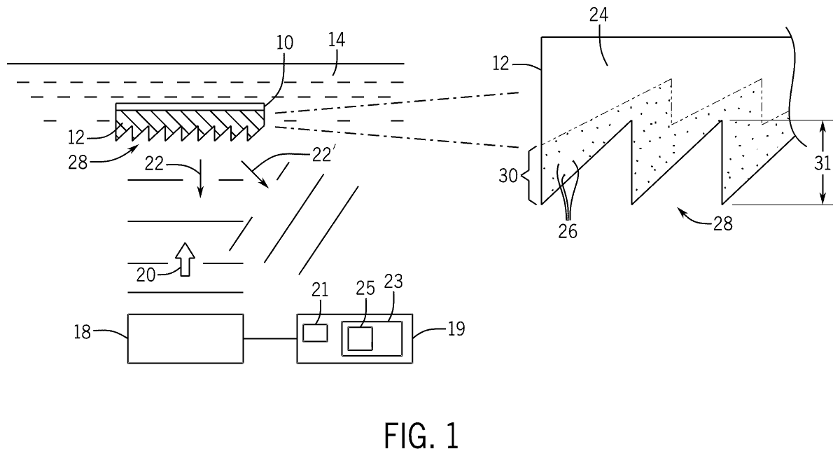

Referring now to FIG. 1, an object 10 incorporating a metamaterial 12 may be suspended in an aqueous environment 14, the latter defined as water or a liquid with an average density close to water (for example, having a specific gravity of 0.4-2). An ultrasound transducer 18 is immersed in or coupled to the aqueous environment 14 to direct a driving ultrasonic signal 20 toward the metamaterial 12, for example, between 20 kHz and 15 MHz.

The ultrasound transducer 18 will generally communicate with a controller 19 having a processor 21 with electronic memory 23 holding in a stored program 25 an interface circuitry that can output signals to drive the ultrasound transducer 18 to control the timing, strength, profile, and phasing (when the ultrasound transducer 18 is an array) of the ultrasound transducer 18.

The object 10 may be submerged in the aqueous environment 14 or floating the surface of the aqueous environment 14 and thus may be either buoyant or have a slightly negative buoyancy as will be discussed below. The ultrasound transducer 18 will generally be positioned beneath the object 10 to direct the driving ultrasonic signal 20 upward to the metamaterial 12 causing either a downward reflection 22 off of a reflecting surface provided by the metamaterial 12 and aligned with the gravitational vector, or at an angled reflection 22′ downward but tipped with respect to the gravitational vector. In the former case, a momentum transfer to the object 10 caused by the downward reflection 22 will produce a levitating effect to overcome any negative buoyancy of the object 10. In the latter case, the momentum transfer to the object 10 caused by the angle the angled reflection 22′ may serve to impart lateral forces on the object 10 perpendicular to the gravitational vector for lateral translation, rotation, or centering as will be discussed. The metamaterial 12 may be constructed to promote either or both of the downward reflection 22 and angle of reflection 22′.

Referring still to FIG. 1, the metamaterial 12 is composed of a matrix material 24 having higher density inclusions 26, the latter of which promote an impedance mismatch with the aqueous environment 14 boosting the reflections 22 and/or 22′. In some examples, the matrix material 24 may be a polymer selected to be resistant to the aqueous environment and to allow the formation of a metamaterial surface pattern 28 on a surface of the metamaterial exposed to the driving ultrasonic signal. In some cases, the polymer may be an elastomer such as polydimethylsiloxane or a silicone polymer; however, other readily available materials are contemplated including, for example, epoxy resin, wax, and the like. To maximize acoustic reflection, relatively inelastic (not elastomer) matrix materials 24 may be preferred; however, elastic materials provide other benefits.

The matrix material 24 need not in itself be highly reflective in the aqueous environment 14, and generally will not be, instead having an acoustic impedance, for example, measured as the product of sound speed and density, similar to that of water. In this respect, the matrix material 24 may have a specific gravity close to that of the aqueous environment 14 and typically a density of less than 2.5 g/cm³.

In contrast to the matrix material 24, the inclusions 26 will desirably have an acoustic impedance (sound speed-density product) that differs significantly from that of the aqueous environment 14 to promote reflections off of the metamaterial 12 when incorporated into the matrix material 24. For example, the acoustic impedance of the inclusions 26 may be ten times or in some cases fifteen times greater than that of the matrix material 24 or aqueous environment 14. Generally, the density of the material of the inclusions 26 will be greater than 3 g/cm³ and preferably greater than 5 g/cm³ and for that purpose may be selected from metals such as iron, steel, copper and the like, or metal compounds including metallic-based ceramics such as aluminum oxide, barium titanate, zirconate niobate, or zirconium dioxide.

The inclusions 26, measured independently of the metamaterial 12, will generally provide an acoustic reflection coefficient in water of greater than 0.5 whereas the matrix material 24, independent of the inclusions 26, will generally provide an acoustic reflection coefficient in water of less than 0.5. Generally, the meta-material 12 will provide an acoustic reflection coefficient in water of greater than 0.5 and typically greater than 0.6 or 0.7. Acoustic reflection coefficient R may be calculated from the formula of:

$$\vert R \vert = \frac{{Z}_{metamaterial} - {Z}_{water}}{{Z}_{metamaterial} + {Z}_{water}}$$

where impedance Z=ρc; and
where ρ is density and c is acoustic wave speed.

The size of the inclusions 26, for example, measured as a diameter of a smallest sphere that encircles the inclusion 26, will generally be less than 1500 micrometers thus being less than or equal to the wavelength of an expected driving ultrasonic signal 20 of 1 MHz to 3 MHz. Typically, the inclusions 26 may have sizes in the range from 5 to 250 μm.

In some embodiments, the inclusions may be concentrated within a displacement region 30 extending from the sound receiving surface of the metamaterial 12 by a distance equal to approximately ⅕ of the wavelength of the received ultrasound signal, for example, 100 μm for a 3 MHz signal and more broadly, less than 1500 μm for most applications. Such a concentration, for example, may provide for a five times greater volume density within the displacement region 30 than outside of the displacement region 30. More generally, the density of the inclusions 26 within the matrix material 24 may be as high as mechanically practical but may be beneficially limited to less than 85% and, in some cases 80%, by weight representing a good trade-off between acoustic effect and avoidance of unnecessary weight.

As noted, a sound-receiving surface of the metamaterial 12 will hold a pattern 28 defining a reflection surface promoting predetermined reflection directions with respect to the reflection surface. The reflection surface may be defined as extending along the broadest dimension of the area having the pattern 28 and will generally be positioned to be perpendicular to the axis of propagation of the driving ultrasound signal 20. The present invention can be usefully used with objects 10 having a reflection surface that is substantially larger than the wavelength of driving ultrasound signal 20, for example, greater than ten or greater than twenty times that wavelength, which will typically result in a reflection surface of greater than 1 cm in the largest dimension or one square centimeter in area. There is generally no upper limit on the size of the reflection surface.

Generally, the pattern 28 will have a depth 31 measured along the direction of propagation of the driving ultrasound signal 20 equal to at least one half of that wavelength of the driving ultrasound signal 20. For example, the depth 31 may be between 100 μm and 1500 μm, and more typically for a signal ranging between 1 and 3 MHz, between 250 μm to 750 μm. the pattern 28 desirably controls a reflection of the driving ultrasound signal 20 to impart a force to the object 10 to which the metamaterial 12 is attached. Importantly, the metamaterial 12 may produce a reflection resulting in a transverse force on the metamaterial 12 which may be tailored to provide for translation of the object 10 with respect to an axis of the propagation of the driving ultrasound signal 20, a rotation of the object 10 with respect to the axis of the driving ultrasound signal 20, or a centering of the object 10 within the driving ultrasound signal 20.

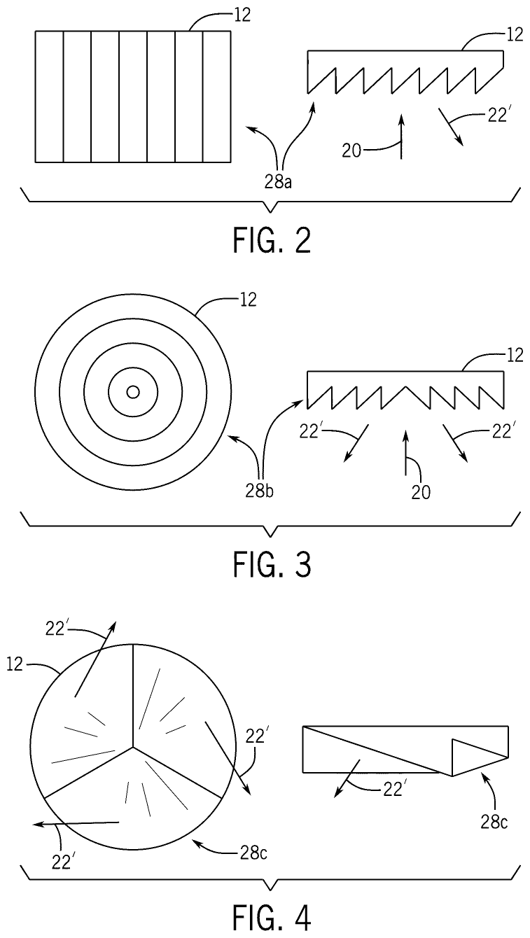

Referring now to FIG. 2, an angled reflection 22′, tipped with respect to the reflection surface normal and typically to the driving ultrasound signal 20, may be obtained with a regular sawtooth pattern 28. This a sawtooth pattern 28 provides a set of angled surfaces reflecting the driving ultrasound signal 20 at the angle of the angled reflection 22′. The height of the surface of the pattern 28 perpendicular to the reflecting surface may be defined as:

$${h}_{pushing} ( x ) = mod ( tan ( α ) x , \frac{λ}{2} )$$

where:
x is a distance along the reflecting surface, a is the angle of the pattern 28 with respect to the reflection surface (x direction), and 2 is the wavelength of the driving ultrasound signal 20.

Referring now to FIG. 3, a pattern 28 creating divergent reflections 22′ about the center of the metamaterial 12 will provide a centering action of the metamaterial 12 about a peak energy of the driving ultrasound signal 20. In one example, the surface may be defined as having a height perpendicular to the reflecting surface of h_{centering} defined as:

$${h}_{centering} = mod ( sin ( θ ) \sqrt{{x}^{2} + {y}^{2}} , λ / 2 )$$

where θ defines how the power is divided between levitating reflection 22 and restoring reflection 22′, the latter of which will shift to properly center the object 10 at the local maximum of the driving ultrasound signal 20.

Referring now to FIG. 4, a rotational force on the metamaterial 12 is obtained by creating reflective surfaces in the pattern 28 in the metamaterial 12 that give the reflections 22′ a tangential component about a surface normal to the reflecting surface. In one example, the pattern 28 may be defined as having a height perpendicular to the reflecting surface of h_{rotating} defined as:

$${h}_{rotating} = mod ( RN φ , 2 π ) λ / 4 π$$

where φ is an azimuthal angle (around a centered surface normal to the reflecting surface) and RN is the periodicity of the sloped surfaces creating the torsional reflections along this azimuthal direction.

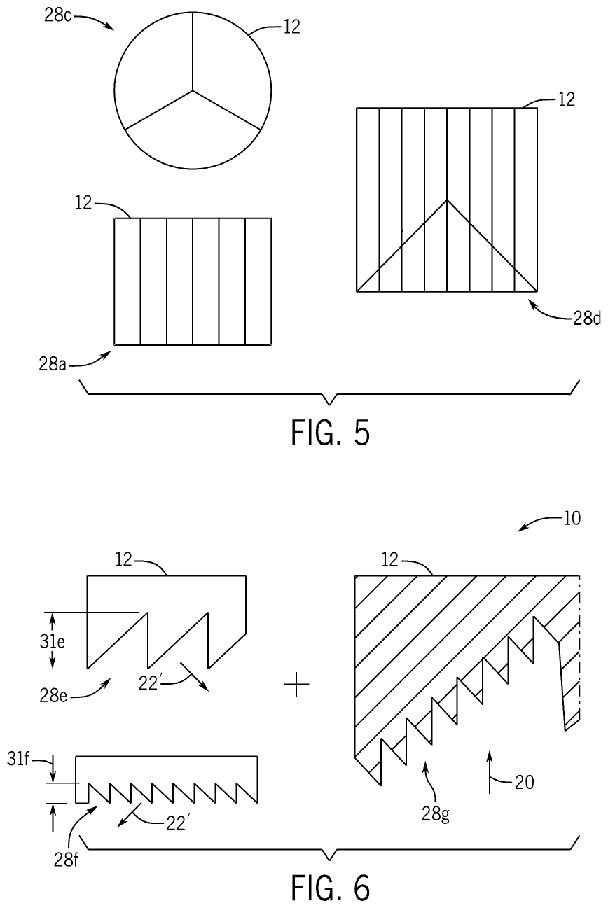

Referring now to FIG. 5, any two or more of these different patterns 28 may be combined by a point-wise addition of the heights generated by the above functions normalized to one-half wavelength. For example, the rotational pattern 28c of FIG. 4 may be combined with the translational pattern 28a of FIG. 2 by an addition process producing a new pattern 28d being a sum superposition of these two patterns according to the following formula:

$${h}_{pushing , rotating} = mod ( 4 π tan ( α ) x + RN φ , 2 π ) λ / 4 π$$

It is contemplated that any combination of the above patterns 28 can be implemented in this manner.

Referring now to FIG. 6, a second type of superposition may combine the above described patterns (in any combination) scaled so that individual patterns 28 will respond only to particular wavelengths of driving ultrasound signal 20. Generally, the reflections 22′ caused by any pattern 28 will be greatly diminished to the extent that the wavelength of the driving ultrasound signal 20 deviates from the half wavelength depth 31 of the pattern 28. This property can be exploited by using a first pattern 28e (for example, per the discussion of FIG. 2 above) having a first depth 31e to provide a rightward reflection 22′ (as depicted) combined with a second pattern 28f having a depth of 31f providing a leftward reflection 22′ (as depicted). In this example, the depth of 31f may be half that of 31e so that pattern 28e is responsive to a first frequency of the driving ultrasound signal 20 and that the pattern 28f is responsive to a second frequency of the driving ultrasound signal 20 being twice that of the first frequency. By controlling the frequency of the driving ultrasound signal 20, therefore, the relative strength of the reflections 22′ for these different patterns 28e and 28f may be controlled allowing leftward or rightward motion to be selected by a frequency multiplexing of the driving ultrasound signal 20. This principle can be extended to multiple patterns 28 sensitive to multiple different frequencies of driving ultrasound signal 20 (which may be sequential or simultaneous) to flexibly implement lateral translation, rotation, and centering in isolation or in combination.

Using a frequency multiplexing approach, in the example of FIG. 1, the relative ratio between the reflection 22 and reflection 22′ may be controlled to provide the desired balance between these two different forces. In this case the pattern 28 will desirably have a spatial periodicity across the broad reflective surface of more than one half the wavelength of the higher frequency.

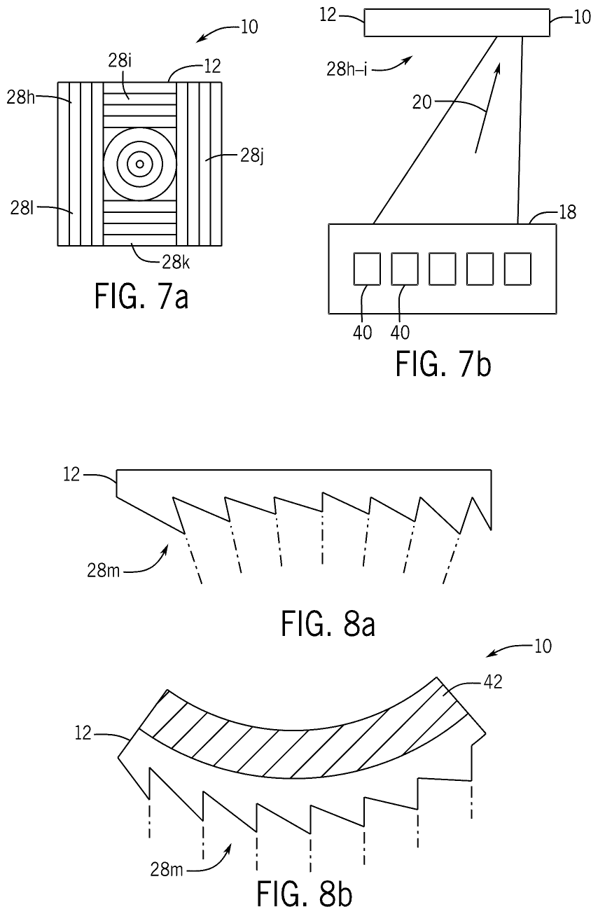

Referring now to FIGS. 7a and 7b, in addition or beyond frequency multiplexing, as discussed with respect to FIG. 6, a spatial multiplexing can be implemented where an object 10 provides for multiple different patterns 28h-28l, implementing variously any of the patterns of FIGS. 2-4 at different locations on the reflective surface. In this case the ultrasound transducer 18 may provide for an array of transducer elements 40 that may be controlled to steer the driving ultrasound signal 20 to different portions of the surface of the metamaterial 12 on the object 10 to selectively reflect off of those different portions to provide a range of different reflections 24′ producing desired motions or effects. In this spatial modulation approach, multiple different patterns can be activated through a rapid spatial switching, or multiple simultaneous steered or focused beams can be used.

Referring now to FIGS. 8a and 8b, the metamaterial 12 when constructed of an elastomeric or malleable material may be fabricated, for example, in a planar state as indicated by FIG. 8a and then applied to a curved surface 42, for example, by adhesive or the like to allow a simple planar manufacturing process to produce a curved metamaterial 12. The pattern 28, in this case, when formed in a flat state, may be modified from the ultimately desired pattern 28 on the curved surface, for example, as described with respect to FIGS. 2-4, by anticipating application to the curved surface 42 to distort the manufactured pattern 28m so that when the metamaterial 12 is curved, it produces a new pattern 28m′ having desired reflective properties. Note that in these cases, the above described equations for the various patterns 28 would represent deviations from the curvature of the curved surface or heights referenced to that curved surface.

The above described metamaterial 12 may be used not only for imparting motion to an attached object but for other purposes such as sound absorption, cloaking, or obscuring an object. For example, a cloaking may use the pattern of FIG. 2 to deflect ultrasound energy away from a sonar transceiver and the pattern of FIG. 3 may be used to make the apparent profile of an object smaller or bigger.

Certain terminology is used herein for purposes of reference only, and thus is not intended to be limiting. For example, terms such as “upper”, “lower”, “above”, and “below” refer to directions in the drawings to which reference is made. Terms such as “front”, “back”, “rear”, “bottom” and “side”, describe the orientation of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

When introducing elements or features of the present disclosure and the exemplary embodiments, the articles “a”, “an”, “the” and “said” are intended to mean that there are one or more of such elements or features. The terms “comprising”, “including” and “having” are intended to be inclusive and mean that there may be additional elements or features other than those specifically noted. It is further to be understood that the method steps, processes, and operations described herein are not to be construed as necessarily requiring their performance in the particular order discussed or illustrated, unless specifically identified as an order of performance. It is also to be understood that additional or alternative steps may be employed.

References to “a microprocessor” and “a processor” or “the microprocessor” and “the processor,” can be understood to include one or more microprocessors that can communicate in a stand-alone and/or a distributed environment(s), and can thus be configured to communicate via wired or wireless communications with other processors, where such one or more processor can be configured to operate on one or more processor-controlled devices that can be similar or different devices. Furthermore, references to memory, unless otherwise specified, can include one or more processor-readable and accessible memory elements and/or components that can be internal to the processor-controlled device, external to the processor-controlled device, and can be accessed via a wired or wireless network.

It is specifically intended that the present invention not be limited to the embodiments and illustrations contained herein and the claims should be understood to include modified forms of those embodiments including portions of the embodiments and combinations of elements of different embodiments as come within the scope of the following claims. All of the publications described herein, including patents and non-patent publications, are hereby incorporated herein by reference in their entireties

To aid the Patent Office and any readers of any patent issued on this application in interpreting the claims appended hereto, applicants wish to note that they do not intend any of the appended claims or claim elements to invoke 35 U.S.C. 112(f) unless the words “means for” or “step for” are explicitly used in the particular claim.

What we claim is:

1. An acoustic reflector comprising matrix material having impedance boosting inclusions with a higher density than the matrix material, the acoustic reflector providing a reflection surface exposing a raised surface pattern adapted to preferentially reflect an aqueously transmitted acoustic signal in least one predetermined direction at a nonzero angle with respect to a broadest extent of the reflection surface;
wherein the impedance boosting inclusions may have an acoustic impedance (Z=ρc) greater than 4.5 MPa·S/m3 and the matrix material has an acoustic impedance less than 3 MPa·S/m3.

2. The acoustic reflector of claim 1 wherein the inclusions have a greatest dimension less than 1500 μm.

3. The acoustic reflector of claim 1 wherein the inclusions are selected from the group consisting of metal and metal compounds.

4. The acoustic reflector of claim 1 wherein the inclusions have an average concentration in a region of the matrix material within 1500 micrometers of a surface of the acoustic reflector receiving the transmitted acoustic signal, at least five times an average concentration outside of that region within the matrix material.

5. The acoustic reflector of claim 1 wherein inclusions have a mass ratio to the matrix within 1500 micrometers of a surface of the acoustic reflector receiving the transmitted acoustic signal of less than 85%.

6. The acoustic reflector of claim 1 wherein the matrix material is a polymer.

7. The acoustic reflector of claim 6 wherein the matrix material is an elastomer.

8. The acoustic reflector of claim 1 wherein the predetermined direction is selected from a direction promoting a translation force angled with respect to a perpendicular to a broadest extent of the reflection surface and a direction having a tangential component around a perpendicular to the broadest extent of the reflection surface.

9. The acoustic reflector of claim 8 wherein the predetermined direction is such as to produce a translation force centering the acoustic reflector about a local maximum of the acoustic signal strength of an ultrasound signal impinging on the reflection surface.

10. The acoustic reflector of claim 1 wherein the predetermined direction is such as to provide a force promoting a combination of rotation and translation of the acoustic reflector.

11. The acoustic reflector of claim 1 wherein the surface pattern includes a first sub-pattern adapted to reflect an aqueously transmitted acoustic signal in a first predetermined direction angled with respect to the broadest extent of the reflection surface and a second pattern adapted to reflect an aqueously transmitted acoustic signal in a second predetermined direction, different from the first predetermined direction and angled with respect to the broadest extent of the reflection surface.

12. The acoustic reflector of claim 11 wherein the first and second sub-patterns are superimposed on the reflection surface.

13. The acoustic reflector of claim 1 wherein the surface pattern includes a first sub-pattern adapted to reflect an aqueously transmitted acoustic signal at a first frequency to impose a force along at least one predetermined direction sufficient to move the matrix material in response to that force and a second sub-pattern adapted to reflect an aqueously transmitted acoustic signal at a second frequency different from the first frequency to impose a different force along at least one second different predetermined direction different from the at least one predetermined direction.

14. The acoustic reflector of claim 13 wherein the first and second frequencies are above 200 kHz.

15. The acoustic reflector of claim 1 wherein the impedance boosting inclusions have a density greater than 3 g/cm³ and the matrix material has a density less than 2.5 g/cm³.

16. The acoustic reflector of claim 1 wherein the meta-material has an acoustic reflection coefficient of greater than 0.5 and the matrix material has a reflection coefficient of less than 0.5 in isolation from the impedance boosting inclusions.

17. An apparatus for acoustic levitation comprising:
an acoustic transmitter adapted to couple an acoustic signal into an aqueous medium;
an acoustic reflector comprised of matrix material having impedance boosting inclusions with a higher density than the matrix material, the acoustic reflector providing a reflection surface exposing a raised surface pattern adapted to preferentially reflect an aqueously transmitted acoustic signal in least one predetermined direction at a nonzero angle with respect to the reflection surface; wherein the impedance boosting inclusions have a density greater than 3 g/cm³ and the matrix material has a density less than 2.5 g/cm³; and
wherein the acoustic signal operates to move the matrix material in response to a force generated by the preferential reflection of the raised surface pattern.

18. The apparatus of claim 17 wherein the acoustic reflector has a negative buoyancy and wherein the reflection surface further reflects the aqueously transmitted acoustic signal perpendicular to the reflection surface to create an upward force on the acoustic reflector overcoming the negative buoyancy.
